(19) United States
(12) Patent Application Publication
(10) Pub. No.: US 2008/0175311 A1
(43) Pub. Date: Jul. 24, 2008

(54) OVERSAMPLING TRANSVERSAL EQUALIZER

(76) Inventor: Tatsuaki KITTA, Kawasaki (JP)

Correspondence Address: ARENT FOX LLP, 1050 CONNECTICUT AVENUE, N.W., SUITE 400, WASHINGTON, DC, 20036, US

(21) Appl. No.: 12/058,189

(22) Filed: Mar. 28, 2008

Related U.S. Application Data
(63) Continuation of application No. PCT/JP2005/018196, filed on Sep. 30, 2005.

(51) Int. Cl. H03H 7/40

(52) U.S. Cl. 375/232

(57) ABSTRACT

An equalizer comprises: a calculation unit performing calculation of a tap coefficient for each symbol interval; an interpolation unit obtaining, by performing interpolation, a tap coefficient that has become necessary due to oversampling, including a tap coefficient of a symbol interval, by using a tap coefficient of the symbol interval output from the calculation unit; a filter unit performing equalization on an input signal by using the tap coefficient obtained by the interpolation unit; and a thinning unit thinning data of a sampling interval output from the filter unit into data of the symbol interval to be used as output from the oversampling transversal equalizer.

### CROSS-REFERENCE TO RELATED APPLICATION

This application is a continuation of international PCT application No. PCT/JP2005/018196 filed on Sep. 30, 2005.

### BACKGROUND

1. Field

The present embodiment relates to an equalization method of received signals in communication systems. For example, the present embodiment may relate to an oversampling transversal equalizer used for demodulation units in radio receiver devices that employ the multi-level QAM modulation.

2. Description of the Related Art

In a digital radio communication system, the multi-level QAM (quadrature amplitude modulation) method is often employed because it permits the transmission of a large amount of data in a limited bandwidth. In the multi-level QAM method, the quiescent-carrier AM modulation is performed by using baseband signals respectively having multiple values (two values, four values, N values) on two carrier waves whose phases are different by π/2 (orthogonal) to each other, the combined signal is transmitted, the received signal is converted into a signal of an intermediate frequency (IF) after passing through a reception filter for, e.g., removing unnecessary signals in the receiver side, the signal is equalized in order to compensate for distortion caused on transmission paths by using an equalizer that is adaptable to various states of the transmission paths, and the signal is demodulated.

FIG. 14 shows an example of a conventional oversampling transversal equalizer used for a demodulation unit in a digital CATV receiver device that employs the multi-level QAM modulation. This example is a configuration obtained by applying, for example, the four-times oversampling to an oversampling transversal equalizer disclosed in Patent Document 1.

In FIG. 14, FFs 100 that operate with a sampling clock are flip flop circuits that latch input data at the rising edge of, for example, the sampling clock. Delay devices 101 delay input signals so that data D(or a polarity signal) that results from delays caused by the delay devices 101, an error signal E based on a comparison result of output of the equalizer, and the target signal become data of the same time at the center tap. The delay times caused by the five delay devices 101 are the same. In other words, an input signal is input into a multiplier 106 arranged at a position that is the closest to the input side, and the output from an integrator 105 that is to be multiplied by the input signal corresponds to the tap coefficient of the center tap.

An error signal En of the symbol interval is generated by using an error signal identification unit 103 on the basis of the difference between the targets signal and the output of the equalizer. A piece of error data that occurred at the time when the error data became necessary due to oversampling is interpolated/generated by using various methods such as filter interpolation, linear interpolation, or the like with the error interpolation unit 104 on the basis of the value of the error signal En of the symbol interval, and is output so that it is multiplied, by the multiplier 102, with input identification data D or a signal of a result of delay by the FF100 thereof as error data E of the sampling clock operation i.e., the sampling interval. The identification signals output from the five delay devices 101 vary in accordance with the sampling interval, and the error data that is to be multiplied with this identification signal is generated by the interpolation.

The output of multipliers 102 is integrated by the integrators 105, and the integration result is multiplied by the input signal or the input signal after passing through the FFs 100. The multiplication results are added by an adder 107, and ¼ of this result is thinned out from itself by a rate convertor 108, and this result is output as the output of the equalizer. The input of the rate convertor 108, i.e., the output of the adder 107 is sampling clock operation, and accordingly the output of the rate convertor 108 is based on a symbol interval by providing, to the rate convertor 108, a flip flop circuit operating at, for example, the symbol clock interval. This conventional example is an example to which an equalization method called the MZF (modified zero forcing) is applied because the polarity signal input into the multiplier 102 at a stage earlier than the integrator 105 is extracted from the signals before being equalized. Further, the target signal in the conventional example in FIG. 14 corresponds to +2, +1, −1, and −2 in the signal wave form shown in FIG. 15 (this will be explained later).

### Patent Document 1:

Japanese Patent Application Publication No. 5-90896 “Oversampling transversal equalizer”

In the conventional example shown in FIG. 14, a piece of error data occurring at a necessary timing due to the oversampling is interpolated/generated by using an error interpolation unit 104, and accordingly it is not always possible to accurately calculate error data, and thus the accuracy of the tap coefficient calculated on the basis of the error data is low, which causes a deterioration of the performance of equalizers.

FIG. 15 shows this problem. In the error data that is inherently necessary for operating oversampling transversal equalizers at a high accuracy, there is a difference between the ideal envelope curve and the actual envelop of the signals respectively at the sampling points, which is represented by the white arrows and the black allows in FIG. 15. For example, in the conventional example shown in FIG. 14, only the error data at the EYE pattern opening, i.e., the error data that becomes necessary due to the oversampling with the interpolation by using the while arrows, i.e., the differences indicated by the black arrows, are obtained. However, in this method, the trace of the actual envelope curve cannot be reflected. In other words, even when the same distortions are caused, if the envelopes have different traces, different pieces of error data can be obtained. However, in the conventional example, the change of the trace of the actual envelope curve of the error data cannot be reflected because the interpolation is performed, and therefore accurate error data cannot be calculated, which is problematic.

### SUMMARY

It is an aspect of the embodiments discussed herein to provide an oversampling transversal equalizer according to the present invention includes: a tap coefficient calculation section performing calculation of a tap coefficient for each symbol interval; and a filter performing equalization on an input signal by using the obtained tap coefficient.

These together with other aspects and advantages which will be subsequently apparent, reside in the details of construction and operation as more fully hereinafter described and claimed, reference being had to the accompanying drawings forming a part hereof, wherein like numerals refer to like parts throughout.

### BRIEF DESCRIPTION OF THE DRAWINGS

FIG. 1 is a block diagram showing the principle of an oversampling transversal equalizer according to the present invention;

FIG. 2 is a block diagram that shows an entire configuration of a QAM demodulation unit in which the oversampling transversal equalizer according to the present invention is used;

FIG. 3 is a block diagram showing a fundamental configuration of a first example of the present invention;

FIG. 4 is a block diagram showing a detailed configuration of the first example of the present invention;

FIG. 5 shows time adjustment between an error signal and a polarity signal in the first example of the present invention;

FIG. 6 shows an example of a configuration of an integrator according to the first example in the first example of the present invention;

FIG. 7 is a block diagram showing a configuration of an interpolation filter according to the first example of the present invention;

FIG. 8 shows operation of the interpolation filters shown in FIG. 7;

FIG. 9 shows an impulse response of the interpolation filters shown in FIG. 7;

FIG. 10 is a block diagram that shows in detail a configuration of a tap coefficient interpolation unit;

FIG. 11 shows an operation time chart covering from the start until the output of the tap coefficients in the first example of the present invention;

FIG. 12 is a block diagram showing a fundamental configuration of a second example of the present invention;

FIG. 13 is a block diagram showing a detailed configuration of the second example of the present invention;

FIG. 14 shows an example of a conventional oversampling transversal equalizer; and

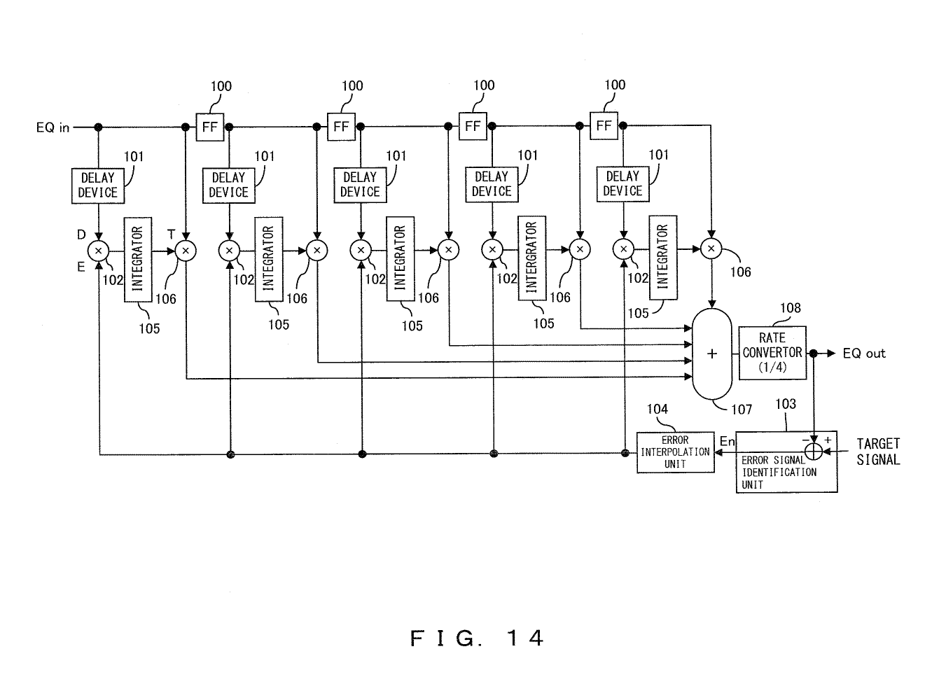

FIG. 15 shows a problem in the example of the conventional oversampling transversal equalizer.

### DESCRIPTION OF THE PREFERRED EMBODIMENTS

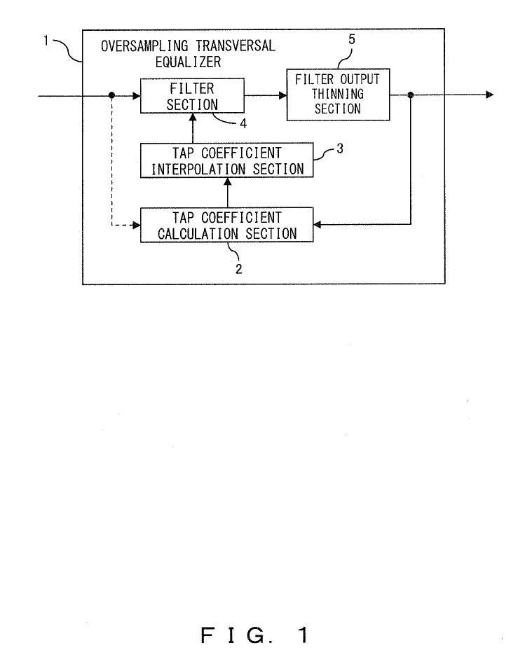

FIG. 1 is a block diagram showing the principle of an oversampling transversal equalizer according to the present invention. In FIG. 1, an oversampling transversal equalizer 1 may include at least a tap coefficient calculation section 2, a tap coefficient interpolation section 3, and a filter 4. The oversampling transversal equalizer 1 may also include a filter output thinning section 5.

The tap coefficient calculation section 2 performs operation of the tap coefficient for each symbol interval. The tap coefficient interpolation section 3 obtains the tap coefficient that has become necessary due to oversampling with the interpolation by using the tap coefficient for each symbol interval as the result of the above calculation. The filter 4 performs the equalization on the input signals by using the tap coefficient obtained by the tap coefficient interpolation section 3.

The filter output thinning section 5 thins (performs rate conversion on) the data of the sampling clock interval output from the filter 4, and uses the result as the output of the oversampling transversal equalizer. In the present invention, the tap coefficient calculation section 2 can further include an error signal identification unit that compares the output of the filter output thinning section 5 and the target signal in order to output an error signal on the basis of the comparison result.

In the first embodiment of the present invention (which will be described later), in addiction to the error signal identification unit, the tap coefficient calculation section 2 may further include an input signal thinning unit for thinning (performing a rate conversion on) the data of the sampling clock interval as the input to the filter 4 into data of the symbol interval, and an input signal identification unit for extracting an identification signal from the output of the input signal thinning unit, and can perform calculation of the tap coefficient of the symbol interval by using the output of the above mentioned error signal identification unit and the output of the input signal identification unit. In this case, the input signal thinning unit and the input signal identification unit may have their positions exchanged.

In a second example (that will be explained later) of the present invention, in addition to the above mentioned error signal identification unit, the tap coefficient calculation section 2 may further include an output signal identification unit for extracting an identification signal from the output of the tap coefficient calculation section 2, and can perform operation of the tap coefficient of the symbol interval by using the output of the output signal identification unit and the output of the error signal identification unit.

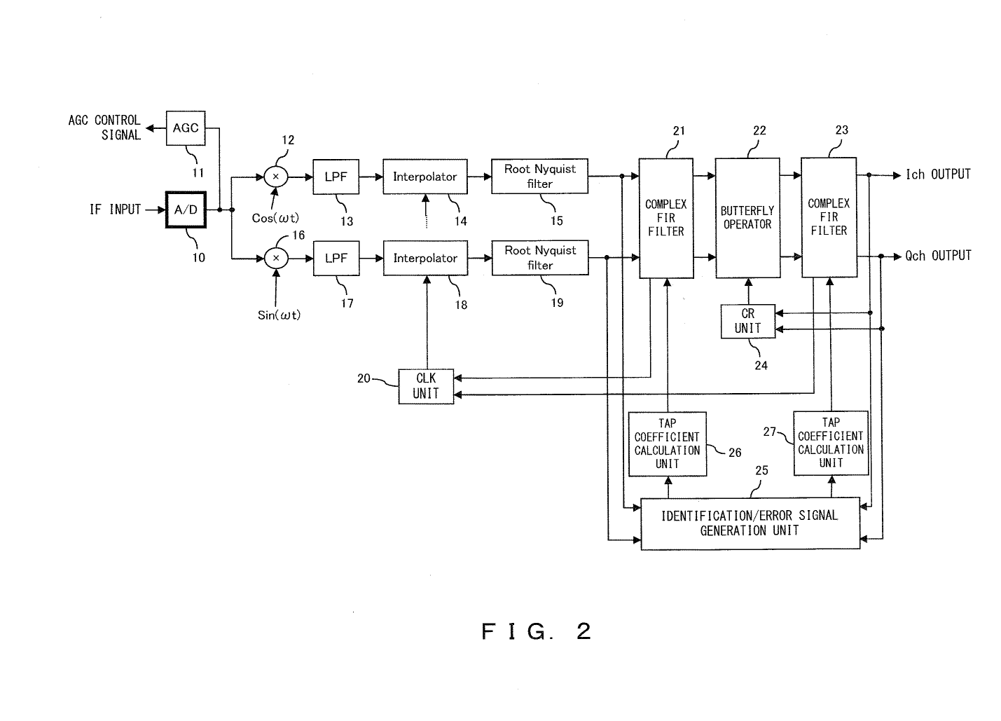

FIG. 2 is a block diagram that shows an entire configuration of a demodulation unit in a receiver device employing the multi-level QAM modulation in which the oversampling transversal equalizer according to the present invention is used. The entirety of the operation of this demodulation unit does not directly relate to the operation of the oversampling transversal equalizer according to the present invention. However, in order to explain the position of the present invention, the operation of this demodulation unit will be explained.

In FIG. 2, an IF signal is given to an A/D convertor 10, and the IF signal is digitalized. This IF signal is a signal that has arrived by means of the bandpass transmission, and has a spectrum with a trapezoidal shape in a certain band. The digitalized IF signal is given to an automatic gain controller (AGC) 11 in order to determine whether or not the power of the digitalized IF signal is greater than a desired value for adjusting the gain of the amplifier of the RF side.

In order to divide the output signal of the A/D converter 10 into an I channel and a Q channel, the multiplication of Cos (ωT) is performed by a multiplier 12, and the multiplication of Sin (ωT) is performed by a multiplier 16. For this multiplication, the center frequency of the trapezoid of the IF signal spectrum is used as the frequency that corresponds to the frequency ω. Because the signals of the upper and lower frequencies are generated by mixing, the output of the multipliers 12 and 16 is given to low-pass filters (LPFs) 13 and 17 respectively, and the components of the upper frequency are cut, and the rest is given to interpolators 14 and 18.

The interpolators 14 and 18 perform the timing reproduction respectively for the I channel and Q channel. The timing reproduction is controlled by control signals output from a CLK unit 20. In the demodulation unit in FIG. 2, the control signal for correcting the timing error is generated on the basis of the digital PPL operation of a loop filter in the CLK unit 20 by using an error signal given from the equalizer that is set in a later stage. The control signal is given to the two interpolators 14 and 18.

The signals of the I channel and the Q channel that have undergone the timing reproduction are input respectively to a route Nyquist filters 15 and 19. This filter is provided also at the transmitter side in order to perform bandwidth restriction as the Nyquist filters on both the transmitter and receiver sides.

The bandwidth restricted signal is given to a complex FIR filter 21. The complex FIR filter 21 operates as a linear equalizer together with another complex FIR filter 23 that is further provided in a later stage. The complex FIR filter 21 removes the interference waves caused when there is a ghost before the desired wave (i.e., in the non-minimum phase), and its output is given to a butterfly operator 22.

The butterfly operator 22 corrects the error of the carrier frequency by using the control signals output from a CR unit 24, and performs the carrier reproduction. In other words, the shift of the carrier frequency is detected from the rotation of the constellation due to the output signals of the I channel and the Q channel after the demodulation, and the control is performed on the butterfly operator 22 so that it stops the rotation of the constellation. The word “constellation” used herein is an arrangement of a quadrangle having four corners on the vector diagram in, for example, 4QAM (QPSK), and when the angles of the four corners are all 90 degrees, the slope of the constellation is determined to be zero, while if one of the angles is not 90 degrees and the quadrangle is slanted, the constellation is determined to be slanted. The carrier reproduction circuit obtains the frequency error by integrating this slope (instantaneous phase error).

The output of the butterfly operator 22 is given to the complex FIR filter 23 serving as the linear equalizer provided in a later stage. This filter mainly removes the interference wave caused when there is ghost after the desired wave (i.e., in the minimum phase). The tap coefficients that have undergone the calculation respectively by tap coefficient calculation units 26 and 27 are given respectively to the two filters 21 and 23. The identification signal and the error signal generated by an error signal generation unit 25 are given to the two tap coefficient calculation units 26 and 27.

When the ZF (zero forcing) method is applied as will be described, the output signals of the I channel and the Q channel as the output of the demodulation unit are used for generating the error data and the identification data, and when the MZF (modified zero forcing) method is applied, they are used for generating the error data. Also, among the two filters constituting the equalizer, the input signals of the I channel and the Q channel to the complex FIR filter 21 in an earlier stage are given to the error signal generation unit 25 in order to be used for generating the identification data when the MZF method is applied. Additionally, the oversampling transversal equalizer in an example that will be described later is assumed to correspond to the complex FIR filter 23 serving as the linear equalizer in a later stage in FIG. 2. This is because the center tap comes to the top, as will be described later.

Here, a concept for applications of the ZF method and the MZF method are explained. In the ZF method, the identification signals are obtained also from the output of the equalizer, and accordingly under bad communication conditions such as with intensive inter-symbol interference, the dropping is sometimes not appropriately performed because the output of an equalizer whose equalization operation has not converged is used. Accordingly, if the equalizer is not operating appropriately, it is better to obtain the identification signal from the input to the equator. This is the concept of the MZF method.

However, in the MZF method, because signals before the equalization are used, the convergence error remains in the equalizer, and the constellation tends to be large (the BER characteristic upon the convergence tends to deteriorate). Accordingly, the MZF method is usually applied in the first phase of the dropping, and the ZF method is used in the final phase of the dropping. Thereby, the equalization output with a small constellation (less BER characteristic deterioration) can be obtained.

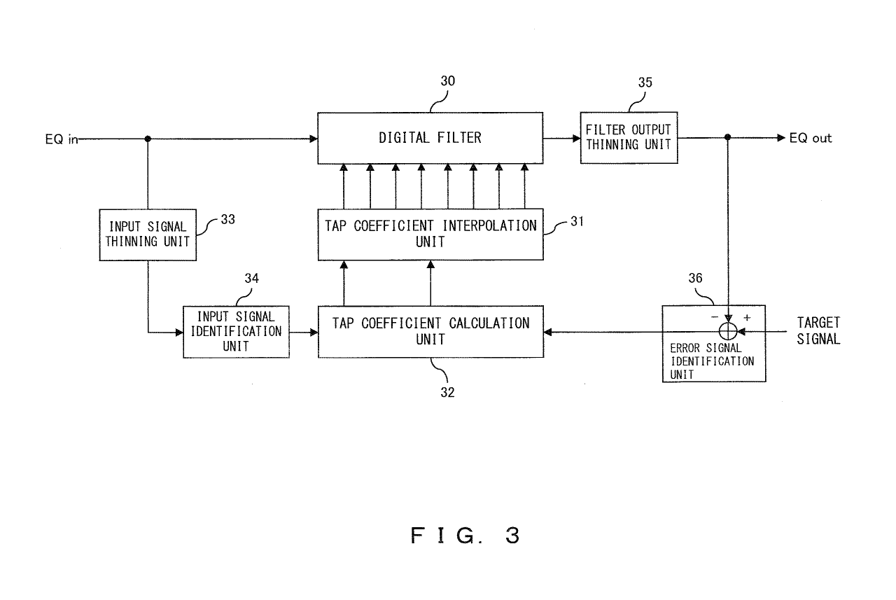

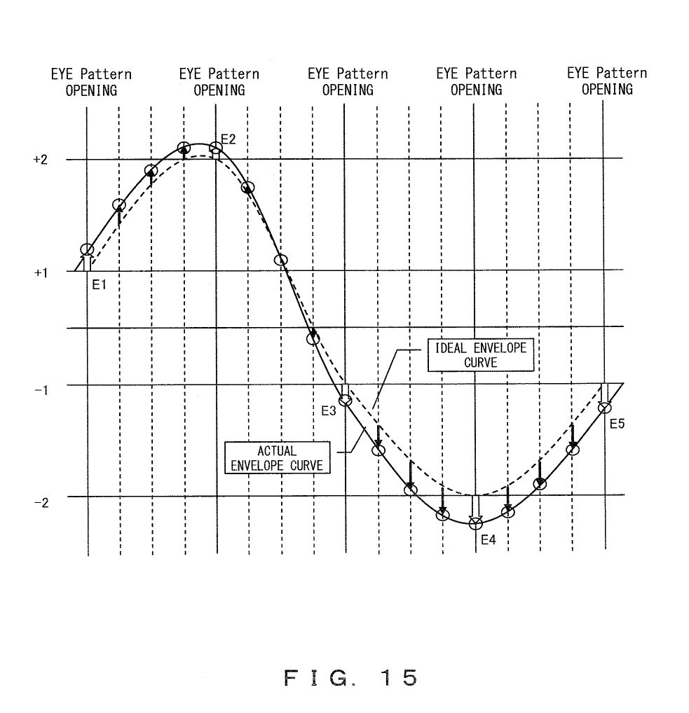

FIG. 3 is a block diagram showing a fundamental configuration of the first example of an oversampling transversal equalizer that employs the MZF method. In FIG. 3, the equalizer includes a digital filter 30 for performing the equalization operation on the input signals; a tap coefficient interpolation unit 31 that includes symbol intervals against the digital filters, i.e., the tap coefficients corresponding to the respective symbols; obtains by the interpolation the tap coefficient that has become necessary due to the oversampling other than the tap coefficient for the EYE pattern openings in FIG. 15, and gives the obtained tap coefficient to the digital filter 30; a tap coefficient calculation unit 32 for performing calculation of the tap coefficient of the symbol interval by using, for example, the LMS (least mean square) algorithm, and for giving the calculation result to the tap coefficient interpolation unit 31; an input signal thinning unit 33 (of rate conversion) for extracting a signal of the symbol interval by thinning the signal of the input signal, i.e, the sampling clock interval; an input signal identification unit 34 for obtaining the value of the identification signal from the output of the input signal thinning unit 33 and giving the result to the tap coefficient calculation unit 32; a filter output thinning unit 35 (for rate conversion) that extracts the signal of the symbol interval from the signal of the sampling clock interval output from the digital filter 30; and an error signal identification unit 36 that compares the signal of the symbol interval as the output of the filter output thinning unit 35 and the target value, and gives an identification error signal based on the comparison result to the tap coefficient calculation unit 32. When the equalizer in this embodiment is applied to a signal having four different amplitude values in the I channel/Q channel of 16QAM, the target signal attains four values, +2, +1, −1, and −2.

As mentioned above, FIG. 3 shows an example of an equalizer that employs the MZF method, and error signals are generated by using the output of the equalizer, and the identification signal is generated by using the input to the equalizer. Also, when the frequency of the symbol clock signal is f and the frequency of the sampling clock signal is nf, i.e., f multiplied by n, the input signal thinning unit 33 generates a signal of frequency f from the signal of the frequency nf, and the filter output thinning unit 35 generates the signal of frequency f from the signal of the frequency nf.

As the identification signal given by the input signal identification unit 34, only a polarity signal indicating whether the signal in 16QAM is greater or smaller than the intermediate level may be used. However, in the QAM having a greater number of values, weighted values such as +2 or −2 may be used. Further, it is also possible to invert the order of the input signal thinning unit 33 and the input signal identification unit 34 in FIG. 3.

Additionally, tap coefficient calculation section in claim 1 of the present application corresponds to a device that is obtained by adding to the tap coefficient calculation unit 32 the error signal identification unit 36, the input signal thinning unit 33, and the input signal identification unit 34 as defined in claims 2, 3, and so on.

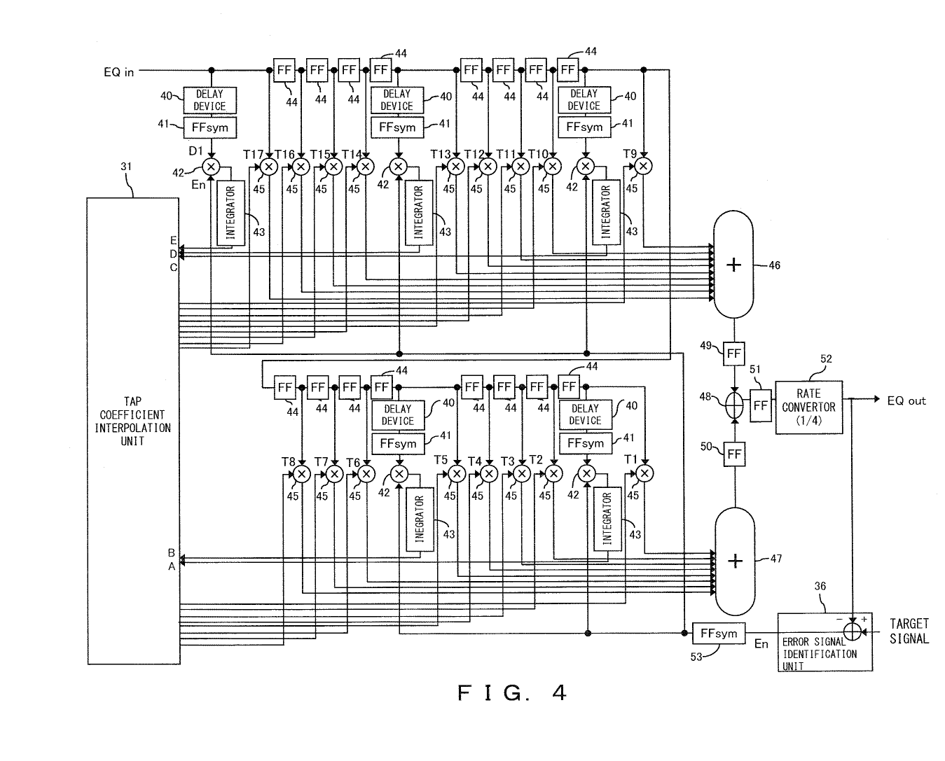

FIG. 4 is a block diagram showing a detailed configuration of the oversampling transversal equalizer in the first example. In FIG. 4, in addition to the tap coefficient interpolation unit 31 and the error signal identification unit 36, the equalizer includes five delay devices 40 for causing the time at which the identification signal obtained from the input signal is input into the equalizer and the time at which the error signal is obtained from the output from the equalizer to be identical to each other; five FFsyms 41, which are flip flop circuits, for latching the output of the delay devices 40 at a symbol interval such as the symbol interval of the rising edge of the symbol clock; five multipliers 42 for multiplying the output from the FFsyms 41 by the error signals obtained from the output from the equalizer; five integrators 43 for integrating the output from the multipliers 42 and giving the results to the tap coefficient interpolation unit 31; sixteen FFs 44 for latching the input data at a sampling interval such as the sampling interval of the rising edge of the sampling clock and delaying the signals by the symbol interval in the four-in-series configuration; seventeen multipliers 45 for multiplying tap coefficients T1 through T17 by the input signal or the output from the sixteen FFs 44; adders 46 through 48 for adding the output from the seventeen multipliers 45; three FFs 49 through 51 for latching the output from the adders 46 through 48 at, for example, the rising edge of the sampling clock; a rate convertor 52 for thinning the output of the FF 51 by ¼; and a flip flop circuit FFsym 53 inserted between the error signal identification unit 36 and the five multipliers 42 and operating at, for example, the rising edge of the symbol clock.

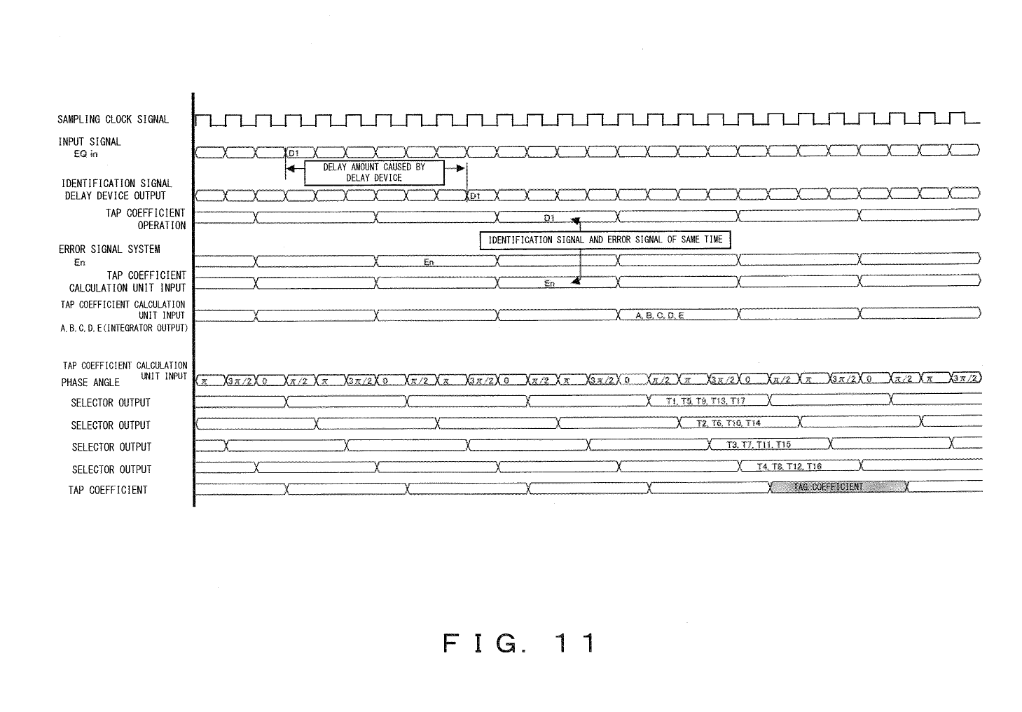

The five delay devices 40 are inserted in order to cause the time at which the identification signal given to the multiplier 42 is closest to the input and the time at which the error signal is generated to be the same to each other, and the respective amounts of delay caused by each of these five delay devices 40 are the same as one another. In order to realize this delay and the delay necessary in the actual implement for realizing the operation time chart explained in FIG. 11, the flip flop circuits 49 through 51 operating at three sampling intervals and the flip flop circuit operating at the symbol interval are used.

The fundamental relationships between the respective blocks in the fundamental configuration view in FIG. 3 and the respective blocks in the detailed configuration view in FIG. 4 are explained. The five delay devices 40 shown in FIG. 4 serve as input identification units 34 for identifying the input signals. All five of the FFsyms 41 correspond to the input signal thinning unit 33. All of the pairs of the multiplier 42 and the integrator 43 correspond to the tap coefficient calculation unit 32. The rate convertor 52 corresponds to the filter output thinning unit 35. All of the constituents except for these blocks, the tap coefficient interpolation unit 31, and the error signal identification unit 36 correspond to the digital filter 30.

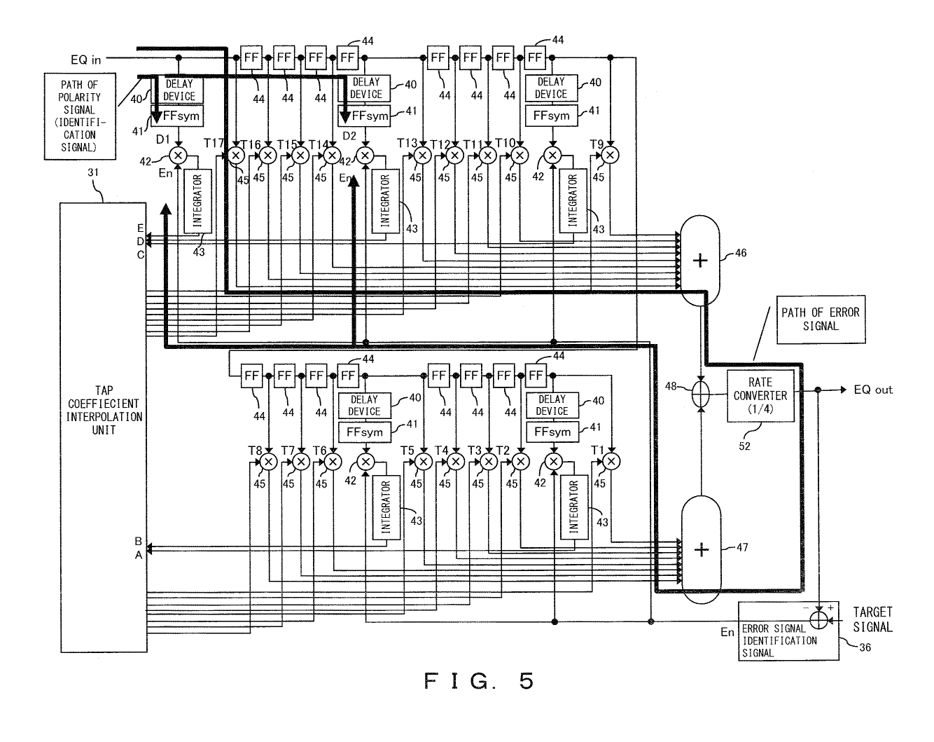

FIG. 5 shows a signal delaying operation performed by the delay devices 40. As mentioned above, the respective amounts of delay caused by each of these five delay devices 40 are the same as one another, and by this delay, the calculation of the tap coefficient of the symbol interval is realized. In FIG. 5, for the explanation of the fundamental operation, the FFs 49 through 51 and the FFsyms 53 shown in FIG. 4 are not shown.

In FIG. 5, the amounts of delay caused by the delay devices 40 are determined so that the time at which an identification signal (polarity signal) D1 is given to the multiplier 42 via the delay devices 40 and the FFsyms 41 directly from the input signal and the time at which an error signal En is obtained from the output of the equalizer become identical to each other. The signal becomes an equalizer-output signal via the multipliers 45, the adders 46 and 48, the rate convertor 52, and the like, to which the input signal and the tap coefficients are input, the error signal is obtained from the output signal, the delay times on the paths of the error signals to the multipliers 42 are determined to be the amounts of delay, and a tap coefficient E is given to the tap coefficient interpolation unit 31 from the integrator 43 that is the closest to the input side.

The input signals are delayed by the delay devices 40 by the same delay amount after passing through the four FFs 44, and are given, as an identification signal D2, to the second multiplier 42 counting from the input side. In other words, the identification signal D2 is the identification signal that is one symbol previous (past), and is multiplied by the error signal En obtained from the equalizer's output at the current time by using the multiplier 42; thereafter, a tap coefficient D of the symbol interval is given to the tap coefficient interpolation unit 31.

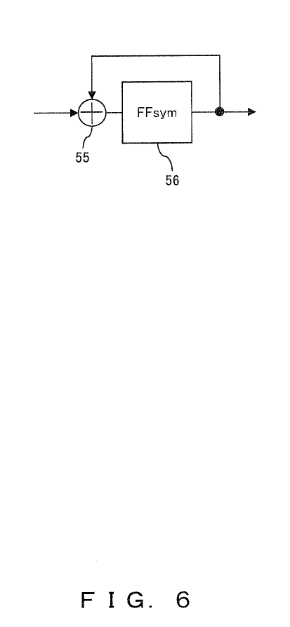

The operation in the first example shown in FIG. 4 will be explained in more detail. FIG. 6 shows an example of a configuration of the integrator 43 shown in FIG. 4. In FIG. 6, the integrator 43 includes an adder 55 and a flip flop circuit FFsym 56 that operates at the symbol interval. The integrator 43 repeats the operation in which the result of adding the input of the multiplier 42 and the content latched by the FFsym 56 is latched while synchronizing with, for example, the rising edge of the symbol clock, and outputs, to the tap coefficient interpolation unit 31, the result as the tap coefficients A, B, C, D, and E for each symbol interval.

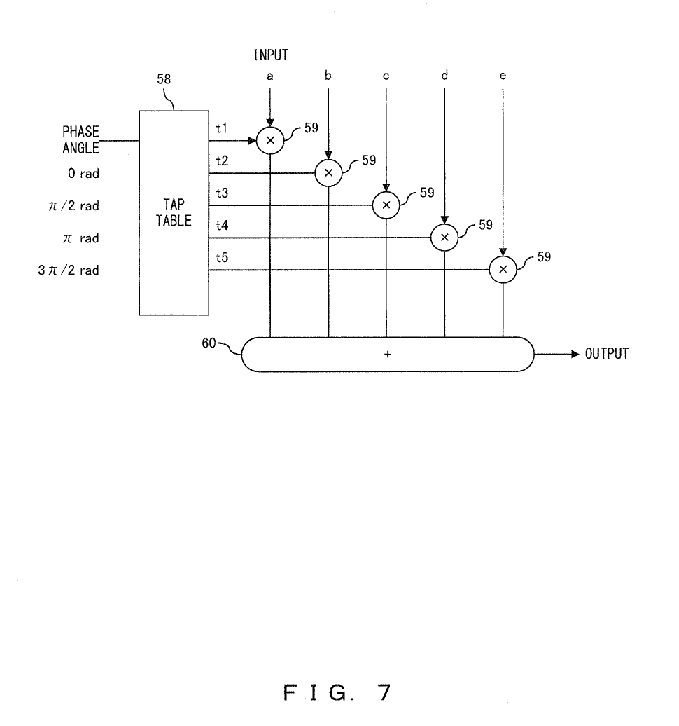

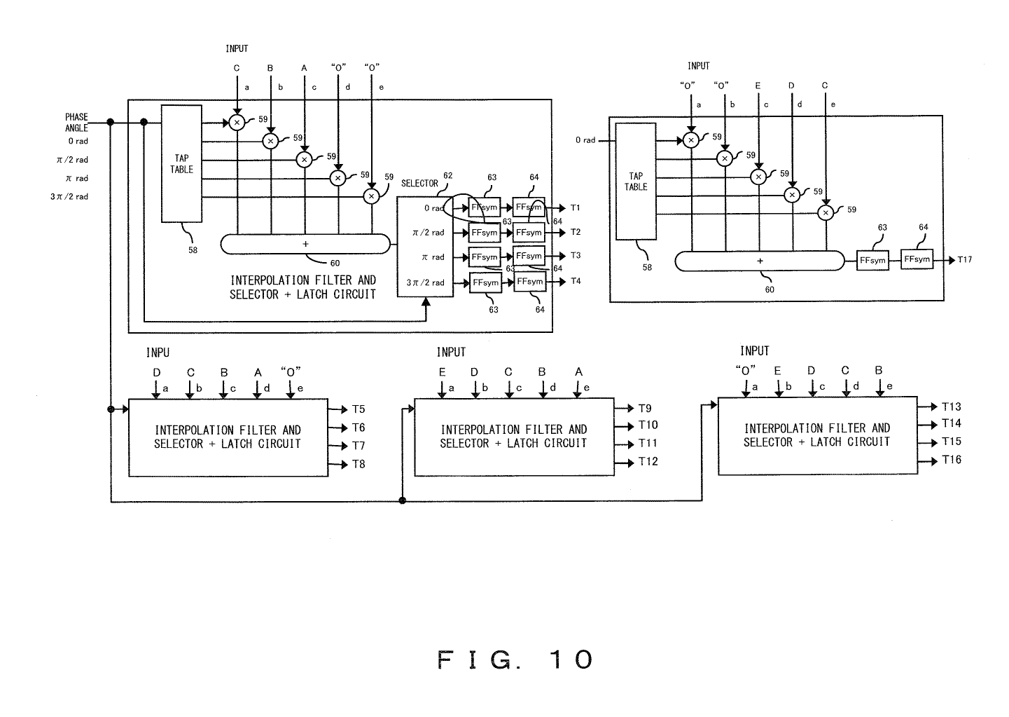

FIG. 7 is a block diagram showing a configuration of an interpolation filter as a main constituent of the tap coefficient interpolation unit 31 shown in FIG. 4. As will be described, five of these interpolation filters are used in the tap coefficient interpolation unit 31, and tap coefficients T1 through T17 in FIG. 4 are output. This will be explained in detail by referring to FIG. 10.

The interpolation filter in FIG. 7 includes a tap table 58 in which data is stored for interpolating the tap coefficients that have become necessary due to oversampling while corresponding to the input of the tap coefficients A, B, C, D, and E output by the integrator 43 shown in FIG. 4, five multipliers 59, and an adder 60 for adding the output from these multipliers 59. In the tap table 58, five pieces of data t1 through t5 that are to be output to the five multipliers 59 while corresponding to the input of the phase angle varying by π/2 at an interval identical to the cycle of the sampling clock of the oversampling i.e., the phase angles of 0, π/2, π, and 3π/2rad when the interval of the symbol is 2πrad, are stored. These pieces of data output from the tap table 58 are multiplied by the tap coefficients A, B, C, D, and E of the symbol interval given to inputs “a” through “e” by using the multipliers 59, as will be explained in FIG. 10, and the multiplication results are added and output from the adder 60. As will be explained by referring to FIG. 10, the inputs “a” through “e” into the five interpolation filters are different from one another, and the tap coefficients T1 through T17 corresponding to the inputs are output in accordance with the value of the phase angle.

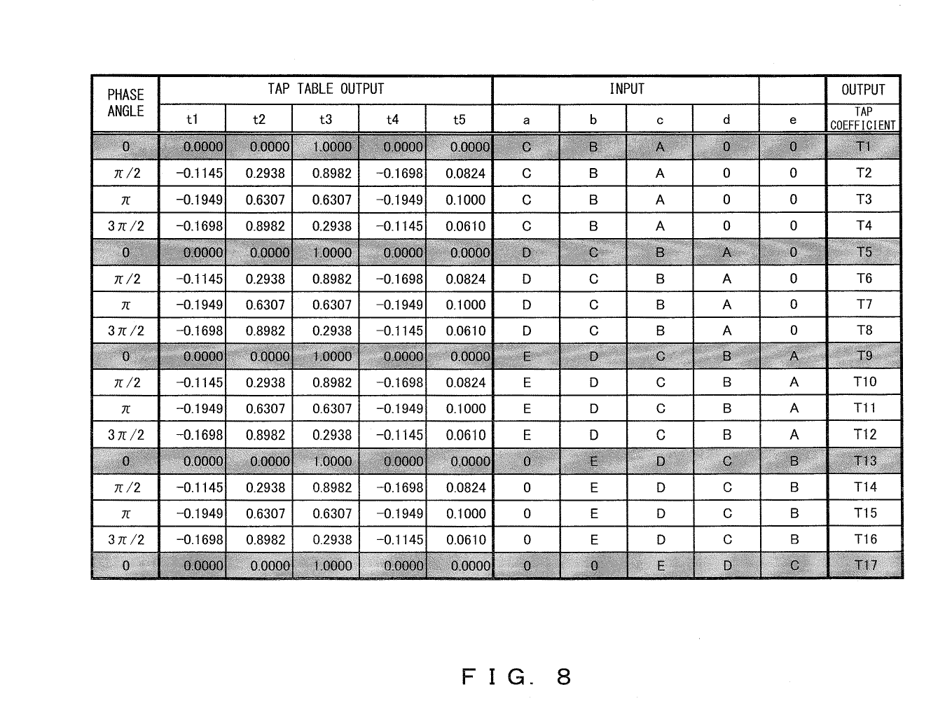

FIG. 8 shows operation of the interpolation filters. Tap table outputs t1 through t5 are output from the tap table 58 shown in FIG. 7. However, these values are determined uniquely by the value of the phase angle input to the tap table 58. The values starting from zero through 3π/2 described on the top four rows on the table shown in FIG. 8 explain the operation of a first interpolation filter among the five interpolation filters. In other words, when the phase angle is zero, zero is given as the tap coefficient C of the symbol interval of the input “a”, as the tap coefficient B of the input “b”, as the tap coefficient A of the input “c”, and as input “d” and “e”. Because only t3 is 1 from among the outputs of the tap table and the others are zero, A is given as the tap coefficient T1.

When the phase angle π/2 is given, the value of

−0.1145×C+0.2938×B+0.8982×A

is output as the tap coefficient T2 against the interpolated oversampling interval, and similarly when the phase angles are π and 3π/2, T3 and T4 are output as the interpolated tap coefficients. In other words, the equalizer according to the present invention uses four-times oversampling, and accordingly three tap coefficients are required between the tap coefficients of the symbol intervals. When the phase angle is zero, the tap coefficient of the symbol point is output, and when the phase angle is π/2, the coefficient is output with the tap at a position away from one of sampling clock; when the phase angle is π, the coefficient is output with the tap at a position away from two of sampling clocks; and when the phase angle is 3π/2, the coefficient is output with the tap at a position away from three of sampling clocks.

The fifth through eighth rows on the table shown in FIG. 8 explain the operation of the second interpolation filter. To this second interpolation filter, D, C, B, A, and zero are given respectively as the input “a”, input “b”, input “c”, input “d”, and input “e”, and when the phase angle is zero, the tap coefficient T5 is output, when the phase angle is π/2, the coefficient T6 is output, when the phase angle is π, the coefficient T7 is output, and when the phase angle is 3π/2, the coefficient T8 is output as the interpolated tap coefficient. Similarly, the ninth through twelfth rows and the thirteenth through sixteenth rows respectively explain the operation of the third and fourth interpolation filters, and the last row of the phase angle zero explains the fifth interpolation filter. In other words, as will be described later, the fifth interpolation filter operates only when the phase angle is zero, and outputs the tap coefficient E of the symbol interval as the tap coefficient T17. The tap coefficient T17 is a tap coefficient of the center tap.

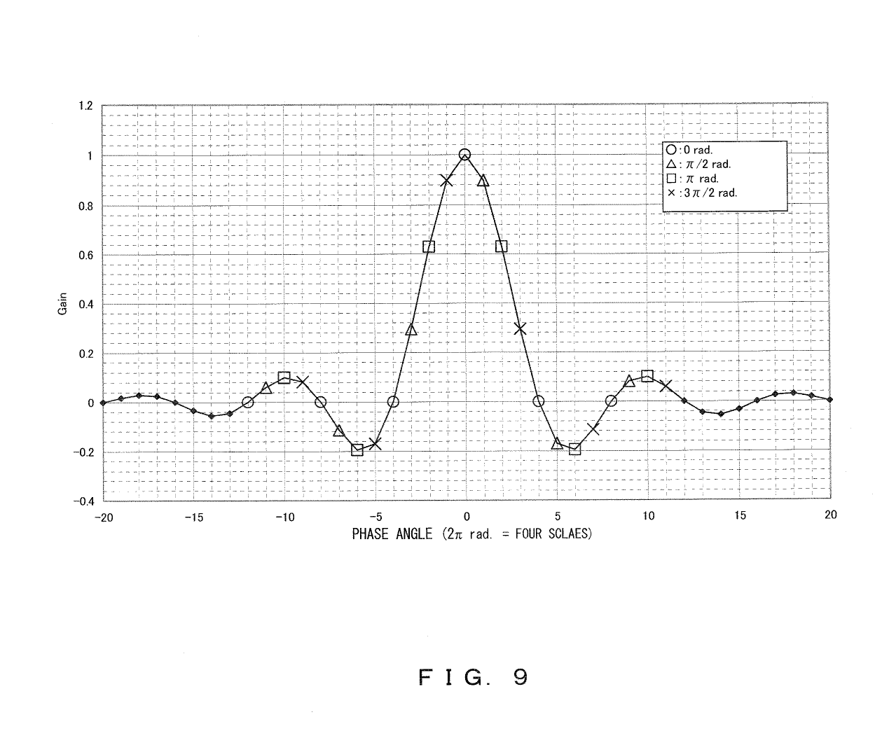

FIG. 9 shows an impulse response made by the interpolation filters in order to give the output of the tap table shown in FIG. 8. From the impulse response shown in FIG. 9, the output values of t1 through t5 on the tap table are determined in the manner described below. First, when the phase angle is zero, the gain “1” of the impulse response with the value of zero as the phase angle (represented by the horizontal axis) is determined to be the value of t3, and the values of the gain that are to the right of the value of t3, i.e., in the positive direction by four graduations (i.e., 2πrad) and by 4πrad (eight graduations) are respectively the values of t4 and t5. Also, the values of the gain that are to the left of the value of t3, i.e., in the negative direction by 2πrad and by 4πrad are respectively the values of t2 and t1.

When the phase angle is π/2rad, the value of the gain that is one graduation to the right of the value of zero of the phase angle (i.e., the value that is indicated by a triangle) is t3, and the values of gain that are 2π and 4πrad away from that value (also indicated by triangles) are t4 and t5. Also, the values of the gain that are 2π and 4πrad to the left are t2 and t1. The values of the output of the tap table when the phase angles are π and 3π/2 can be obtained in the same manner.

The impulse response shown in FIG. 9 is expressed as the even function, and by introducing to this impulse response the time delay corresponding to the delay of the filter, the impulse response that has the causality can be obtained. The tap table for storing the interpolation data determined by this impulse response (i.e., the interpolation data for the tap coefficient calculation that has become necessary due to the oversampling of all except for the symbol point) is written to, for example, a ROM device, and the sampling clock of the oversampling corresponding to the interval of π/2rad of the phase angle is counted by using, for example, a counter, and the output of the tap table is switched on the basis of the value obtained by that counter, and thereby the operation of the interpolation filter explained by referring to FIG. 8 is realized.

FIG. 10 is a block diagram that shows in detail the configuration of the tap coefficient interpolation unit shown in FIG. 4. As was mentioned, the tap coefficient interpolation unit 31 includes the five interpolation filters that were described in FIG. 7, i.e., the interpolation filters that each include the tap table 58, and the tap coefficient interpolation unit 31 also includes five multipliers 59 and the adder 60. The output of the adder 60 as the output of each interpolation filter is input into a selector 62, and the selector 62 outputs, to one of the four FFsyms 63, the output of the adder 60 in accordance with the value of the phase angle, the data that was latched by the FFsyms 63 is further latched by each of the FFsyms 64, and thereafter the latched data is output as the tap coefficient.

The FFsyms 63 and the FFsyms 64 are both flip flop circuits that operate respectively at the symbol clock interval. However, the clock for this operation is not the symbol clock itself, but a symbol clock that has been shifted in time as necessary on the basis of one clock of the sampling clock of the oversampling. The four FFsyms 63 latch, at the symbol interval, the addition result of the adder 60 that was output from the selector 62 in accordance with the phase angle. Also, the FFsyms 64 are flip flop circuits that latch at the same time at the symbol interval in order to update all the tap coefficients at one time.

As was explained by referring to FIG. 8, C, B, A, and zero are given as the inputs “a,” “b”, “c”, “d”, and “e” to the first interpolation filter among the five interpolation filters, and the tap coefficients T1 through T4 are output from the FFsyms 64 that are set later than this interpolation filter.

Similarly, D, C, B, A, and zero are given as the input to the second interpolation filter, the tap coefficients T5 through T8 are output from the four FFsyms 64, E, D, C, B, and A are given as the input to the third interpolation filter, and the tap coefficients T9 through T12 are output. Zero, E, D, C, and B are given as the input to the fourth interpolation filter, and the tap coefficients T13 through T16 are output. Zero, zero, E, D, and C are given as the input to the fifth interpolation filter, and this interpolation filter outputs the addition result of the adder 60 only when the phase angle is 0 rad, and the result is output as the tap coefficient T17 from one of the FFsyms 64.

FIG. 11 shows an operation time chart covering from the start until the output of the tap coefficients in the first example. In FIG. 11, the sampling clock is a clock of the four-times oversampling, and the frequency of the sampling clock is 4 MHz if the frequency of the symbol clock is 1 MHz.

When the data D1 is input through the input EQin in FIG. 4, the data D1 is output and is delayed by, for example, six clocks from the delay device 40 that is the closest to the input if the sampling clock takes the time of six clocks. This data D1 is latched by the FFsym 41 closest to the input at the rising edge of the symbol clock, and is input to the multiplier 42 that constitutes the tap coefficient calculation unit.

The error data En is output from the error signal identification unit 36 serving as an error signal system, the data is latched by the FFsym 53 at the rising edge of the symbol clock, and is input into the five multipliers 42 that constitute the tap coefficient calculation unit. Thereby, in FIG. 4, the identification signal D1 and the error signal En occurring at the same time are given as the signals to the multiplier 42 that is closest to the input.

As was mentioned above, the identification signal given to, for example, the second multiplier 42 counting from the input side, is delayed by one symbol with respect to the error signal En, and the tap coefficient D in accordance with the correlation relationship between the current error signal and the past identification signal that is delayed by one symbol is given to the tap coefficient interpolation unit 31 by the multiplier 42 and the integrator 43 constituting the tap coefficient operation unit. Similarly, the tap coefficients A, B, C, D, and E at the symbol interval output from the five integrators 43 are updated at, for example, the rising edge of the symbol clock.

The lower portion of the time chart represents the operation of the tap coefficient interpolation unit 31. When a tap coefficient of the symbol interval is given to the tap coefficient interpolation unit 31, the calculation of the tap coefficient is performed by using the five interpolation filters each time the phase angles are switched as explained by referring to FIG. 10, and tap coefficients are output from the respective selectors 62. In FIG. 10, it is assumed that the tap coefficient T17 is output from the fifth interpolation filter. However, for simplicity, it is assumed that this time chart corresponds to the first interpolation filter and that the tap coefficient T17 is also output from the selector 62 that outputs the tap coefficients T1, T5, T9, and T13. The addition result that is latched by one of the FFsyms 63 each time the addition result is output from the FFsym 63 is latched by all the FFsyms 64 at the rising edge of the clock that has the same frequency as that of the symbol clock, and all the tap coefficients given to the digital filter 30 in FIG. 3 are updated at one time. Also, the output from the selector shown in FIG. 11 represents the content stored in the FFsyms 63 in FIG. 10, and the output of the tap coefficient represents the content stored in the FFsyms 64.

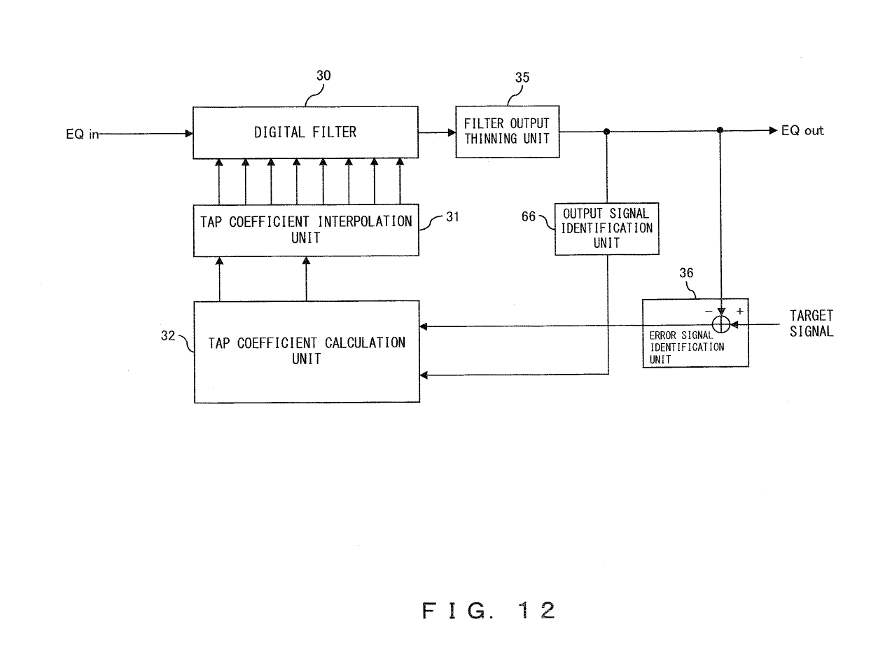

FIG. 12 is a block diagram showing a fundamental configuration of an oversampling transversal equalizer according to a second example of the present invention. The ZF method is applied to this second example. Not only the error signal, but also the identification signal is obtained from the output side of the equalizer, the tap coefficient of the symbol interval undergoes the calculation, and the interpolation of the tap coefficient that has become necessary due to the oversampling is performed by using the tap coefficient of the symbol interval. Accordingly, when FIG. 12 is compared with FIG. 3, which shows a fundamental configuration of the first example, it is recognized that an output signal identification unit 66 for obtaining identification signals from the output side of the equalizer is used in place of the input signal thinning unit 33 and the input signal identification unit 34. In the second example, the tap coefficient calculation section in claim 1 corresponds to a device that is obtained by adding the error signal identification unit 36 and the output signal identification unit 66 to the tap coefficient calculation unit 32 as defined in claims 2 and 7.

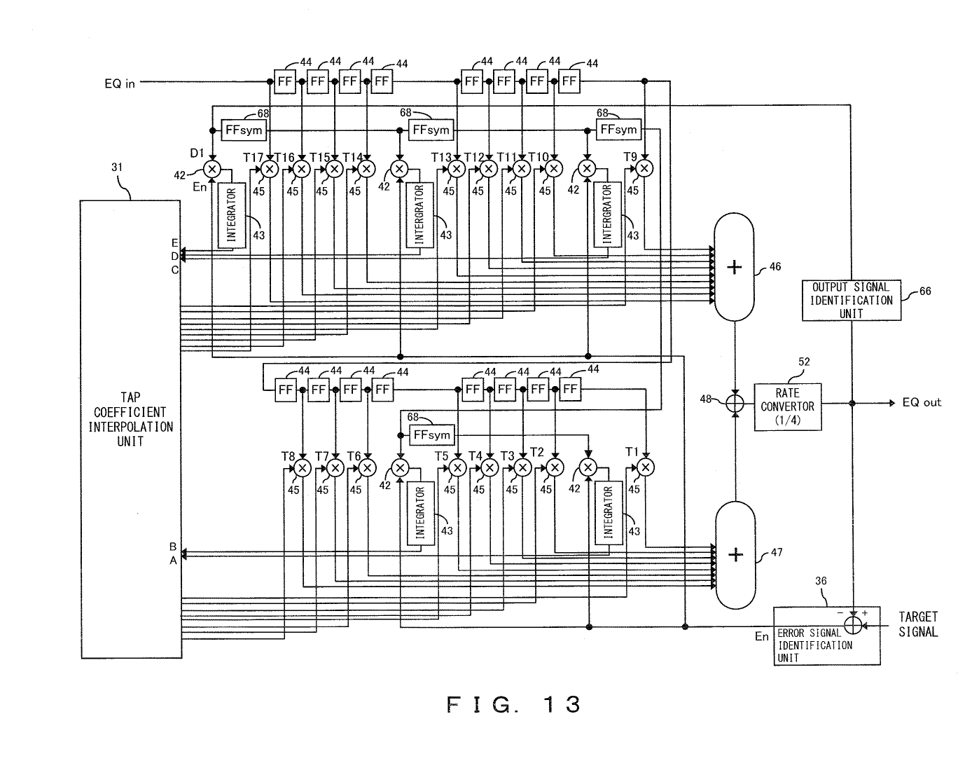

FIG. 13 is a block diagram showing a detailed configuration of the oversampling transversal equalizer according to the second example. When FIG. 13 is compared with FIG. 4, it is recognized that the output signal identification unit 66 and four FFsyms 68 for delaying signals of the identification result of the output signal identification unit 66 are used in place of the five delay devices 40 for obtaining identification signals from the input side of the equalizer and the five FFsyms 41, and that the output of the output signal identification unit 66 or the output of the respective FFsyms 68 is given, as the identification signals that are to be multiplied by the error signals of the current time, to the respective multipliers 42 constituting the tap coefficient calculation unit.

According to an object of the embodiment, it may increase the equalization accuracy of an oversampling transversal equalizer by obtaining a tap coefficient by performing interpolation from the tap coefficient of the symbol interval. This has become necessary due to oversampling performed on the basis of the operation result of the tap coefficient that corresponds to the tap coefficient of the symbol interval, i.e., the EYE pattern opening shown in FIG. 15.

The many features and advantages of the embodiments are apparent from the detailed specification and, thus, it is intended by the appended claims to cover all such features and advantages of the embodiments that fall within the true spirit and scope thereof. Further, since numerous modifications and changes will readily occur to those skilled in the art, it is not desired to limit the inventive embodiments to the exact construction and operation illustrated and described, and accordingly all suitable modifications and equivalents may be resorted to, falling within the scope thereof.

What is claimed is:

1. An oversampling transversal equalizer, comprising:
a tap coefficient calculation section performing calculation of a tap coefficient for each symbol interval;
a tap coefficient interpolation section obtaining, by performing interpolation, a tap coefficient that has become necessary due to oversampling, including a tap coefficient of a symbol interval, by using a tap coefficient of the symbol interval output from the tap coefficient operation section; and
a filter performing equalization on an input signal by using the tap coefficient obtained by the tap coefficient interpolation section.

2. The oversampling transversal equalizer according to claim 1, further comprising:
a filter output thinning section thinning data of a sampling interval output from the filter section into data of the symbol interval to be used as output from the oversampling transversal equalizer, wherein:
the tap coefficient calculation section further comprises:
an error signal identification unit for comparing a target signal and the output of the filter output thinning section, and outputting an identification signal based on a comparison result.

3. The oversampling transversal equalizer according to claim 2, wherein:
the tap coefficient calculation section further comprises:
an input signal thinning unit for thinning data of a sampling interval as input into the filter section into data of the symbol interval; and
an input signal identification unit for extracting an identification signal from output of the input signal thinning unit.

4. The oversampling transversal equalizer according to claim 3, wherein:
the tap coefficient calculation section further comprises:
a multiplier for multiplying an output of the input signal identification unit by an output of the error signal identification unit; and
an integrator for integrating an output of the multiplier.

5. The oversampling transversal equalizer according to claim 2, wherein:
the tap coefficient calculation section further comprises:
an input signal identification unit for extracting identification data from data of a sampling interval as input to the filter section; and
an input signal thinning unit for thinning data of a sampling interval output from the input signal identification unit into data of the symbol interval.

6. The oversampling transversal equalizer according to claim 5, wherein:
the tap coefficient calculation section further comprises:
a multiplier for multiplying an output of the input signal thinning unit by an output of the error signal identification unit; and
an integrator for integrating an output of the multiplier.

7. The oversampling transversal equalizer according to claim 2, wherein:
the tap coefficient calculation section further comprises:
an output signal identification unit for extracting an identification signal from an output of the filter output thinning section.

8. The oversampling transversal equalizer according to claim 7, wherein:
the tap coefficient calculation section further comprises:
a multiplier for multiplying an output of the output signal identification unit by an output of the error signal identification unit; and
an integrator for integrating an output of the multiplier.

9. The oversampling transversal equalizer according to claim 1, wherein:
a tap coefficient interpolation section includes a plurality of interpolation filters for obtaining, by performing internal interpolation using a tap coefficient of the symbol interval, a tap coefficient that has become necessary due to oversampling.

10. The oversampling transversal equalizer according to claim 9, wherein:
each of the plurality of interpolation filters corresponds to two consecutive symbol points, and obtains, by performing interpolation, a tap coefficient corresponding to one of the two symbol points and a tap coefficient corresponding to a moment at which the tap coefficient became necessary due to oversampling between the two symbol points.

11. The oversampling transversal equalizer according to claim 10, wherein:
each of the interpolation filters comprises:
a tap table for storing data corresponding to an impulse response of the interpolation filter;
a plurality of multipliers for multiplying a tap coefficient of the symbol interval by zero or by output data from the tap table; and
an adder for adding multiplication results of the plurality of multipliers.

12. The oversampling transversal equalizer according to claim 11, wherein:
the tap table outputs, to the plurality of multipliers, data corresponding to a phase angle as a variable of a horizontal. axis in the impulse response.

13. The oversampling transversal equalizer according to claim 10, wherein:
the tap coefficient interpolation section comprises:
a plurality of latch circuits respectively corresponding to the plurality of interpolation filters, for temporarily holding output of the interpolation filters; and
a selector for outputting, to one of the plurality of latch circuits, an output of the interpolation filters while corresponding to the phase angle.

14. The oversampling transversal equalizer according to claim 13, wherein:
the plurality of latch circuits give latched data to the filter section at the symbol interval all at one time.

15. The oversampling transversal equalizer according to claim 1, wherein:
the oversampling transversal equalizer is provided to a demodulation unit of a radio receiver device that employs a multi-level quadrature amplitude modulation method.

16. An oversampling transversal equalizer, comprising:
a first tap coefficient calculation section calculating a tap coefficient corresponding to a symbol position of a received signal;
a second tap coefficient calculation section calculating a tap coefficient corresponding to a sampling point other than a symbol position of a received signal from the tap coefficient corresponding to the symbol position when oversampling operation is performed; and
a filter performing equalization on an input signal from the tap coefficient corresponding to the symbol position and the tap coefficient corresponding to the sampling point other than the symbol position.
